(19) United States
(12) Patent Application Publication
(10) Pub. No.: US 2015/0187830 A1
(43) Pub. Date: Jul. 2, 2015

(54) PHOTOSENSITIVE UNIT, ARRAY SUBSTRATE OF DISPLAY PANEL AND MANUFACTURING METHOD THEREOF

(71) Applicant: SHENZHEN CHINA STAR OPTOELECTRONICS TECHNOLOGY CO., LTD., Shenzhen, Guangdong (CN)

(72) Inventor: Tianming Dai, Shenzhen (CN)

(21) Appl. No.: 14/240,361

(22) PCT Filed: Jan. 20, 2014
(86) PCT No.: PCT/CN2014/070906

§ 371 Date: Feb. 21, 2014

(30) Foreign Application Priority Data
Dec. 31, 2013 (CN) 201310753810.X

(51) Int. Cl. H01L 27/146; H01L 31/105; H01L 31/18; H01L 31/028; H01L 31/20

(52) U.S. Cl. CPC H01L 27/14643; H01L 31/028; H01L 31/202; H01L 31/1824; H01L 27/14683; H01L 31/105; H01L 31/1055

(57) ABSTRACT

The present disclosure relates to a photosensitive unit, an array substrate of a display panel and a manufacturing method thereof. In the photosensitive unit, a PIN structure is adopted for photoelectric conversion, and the generated photocurrent has low probability of dramatic change due to the fluctuation of a working voltage, and thus the accuracy is relatively high. In addition, because the photosensitive unit preferably has the PIN structure arranged longitudinally, when the photosensitive unit is configured on the array substrate of the display panel, the sizes of the length, width and height of the intrinsic region can be designed in a more flexible manner. Therefore, the photosensitive region of the photosensitive unit can be enlarged to a maximum extent, and the photoelectric conversion efficiency can be improved. Consequently, the array substrate of the display panel including the photosensitive unit and the display panel have better ambient light sensing capability, high sensitivity and high reliability. The present disclosure is applicable to various display panels.

### FIELD OF THE INVENTION

The present disclosure relates to image display technology, and particularly, relates to a photosensitive unit, an array substrate of a display panel and a manufacturing method thereof.

### BACKGROUND OF THE INVENTION

With continuous improvement of science and technology, the display panel technology is also continuously developed. In recent years, thin film transistor-liquid crystal display (TFT LCD) panel has become a mainstream product on the market due to its excellent performances. A liquid crystal display panel mainly consists of an array substrate, a color filter substrate and a liquid crystal layer, wherein the array substrate consists of a plurality of transistors arranged in an array manner and a pixel unit corresponding to each of the transistors. The transistors serving as switching elements for enabling the pixel units to work receive scan signals from a scan driving circuit through scan lines, receive data signals from a data driving circuit through data lines, and write the data signals into the pixel units under the action of the scan signals. Liquid crystal molecules of the pixel units deflect correspondingly under the action of the data signals, and transmit a certain quantity of light, and at the same time the intensity of the light is adjusted through a peripheral gray-scale adjustment circuit. In this way, image display can be achieved.

In accordance with user requirements that are improved continuously, the current display panel can realize many new functions besides the above-mentioned display function, and has become a multimedia platform with continuously perfected functions. An ambient photosensitive function is one of the new functions integrated in the current display panel. It could be known from the prior art that this function is generally realized by adding a photosensitive unit to the array substrate of the display panel.

FIG. 1 shows a structural section view of a traditional array substrate including a photosensitive unit. The array substrate includes a substrate 10, and a buffer layer 20, a first patterned semiconductor layer 30, a gate insulating layer 40, a first patterned metal layer 50, an interlayer dielectric layer 60 and a second patterned metal layer 70 successively arranged on the substrate 10. After the second patterned metal layer 70 is produced, a first sensing electrode E1 is formed in a photosensitive area, and then a silicon rich oxide (SRO) layer or a silicon rich nitride (SRN) layer is deposited on the first sensing electrode E1, as a photosensitive dielectric layer 80. Subsequently, a second sensing electrode E2 is formed on the photosensitive dielectric layer 80 to complete the photosensitive unit. This photosensitive unit can be produced simply and feasibly. However, due to the single-layer film (one SRO or SRN layer) structure, the resulted photocurrent would be easily dramatically changed due to the fluctuation of working voltage, so that the sensing result is inaccurate.

In the prior art, a liquid crystal display panel with a fingerprint identification function is also provided, wherein a photosensitive unit (as shown in FIG. 2) is also arranged on the array substrate 10 of this display panel. The photosensitive unit includes an active layer 20 with a PIN (P-type doped region/intrinsic region/N-type doped region) structure, a protective layer 30 and a junction 40. When a finger of a user presses the display panel, light emitted by a backlight is transmitted through the pixel units and then irradiated onto the finger, and is further reflected by the finger and then irradiated to the intrinsic region. The intrinsic region absorbs the energy of the reflected light, so that electrons in a valence band are excited to a conduction band. Therefore, holes are left in the valence band to generate equivalent electrons and holes, and thus photocurrent is generated between the P-type doped region and the N-type doped region of the active layer 20, and then output through the junction 40. The photosensitive unit with the PIN structure has low probability of being affected by voltage fluctuation due to relatively stable working property. However, because the PIN structure is transversely disposed and manufactured synchronously with the transistors of a display area of the array substrate, so that the thickness of the PIN structure is low, the photosensitive region is relatively small, and thus the photoelectric conversion efficiency is relatively low.

### SUMMARY OF THE INVENTION

To solve the above-mentioned problems, the present disclosure provides a photosensitive unit with relatively high accuracy and photoelectric conversion efficiency, an array substrate of a display panel, and a manufacturing method thereof.

The present disclosure provides a photosensitive unit configured on an array substrate of a display panel and including: a first conductive doped region; a second conductive doped region; an intrinsic region arranged between the first conductive doped region and the second conductive doped region, wherein the doping ions of the first conductive doped region and those of the second conductive doped region have electric properties opposite to each other; and a first sensing electrode and a second sensing electrode electrically connected with the first conductive doped region and the second conductive doped region respectively.

According to an embodiment of the present disclosure, the first conductive doped region and the second conductive doped region may be made of P-type or N-type ion doped amorphous silicon, and the intrinsic region may be an amorphous silicon layer.

According to an embodiment of the present disclosure, the first conductive doped region and the second conductive doped region may be made of P-type or N-type ion doped microcrystalline silicon, and the intrinsic region may be a microcrystalline silicon layer.

According to an embodiment of the present disclosure, the first conductive doped region and the second conductive doped region may be made of P-type or N-type ion doped microcrystalline silicon, and the intrinsic region may be an amorphous silicon layer.

Further, the first conductive doped region, the second conductive doped region and the intrinsic region are arranged longitudinally.

The present disclosure further provides an array substrate of a display panel having the above-mentioned photosensitive unit arranged thereon.

The present disclosure further provides a method for manufacturing a array substrate of a display panel, including the following steps: providing a substrate including at least one display region and a photosensitive region; forming on the substrate a first patterned semiconductor layer including a first storage electrode and a semiconductor block in the display region, and performing ion doping on the first storage electrode and the semiconductor block, so as to form a source doped region and a drain doped region in the semiconductor block and form a channel region between the source doped region and the drain doped region; forming a gate insulating layer on the substrate to cover the first patterned semiconductor layer; forming on the gate insulating layer a first patterned metal layer including a gate region corresponding to the channel region and a second storage electrode corresponding to the first storage electrode; forming an interlayer dielectric layer on the gate insulating layer to cover the first patterned metal layer; forming a plurality of dielectric layer windows in the interlayer dielectric layer and the gate insulating layer to expose the source doped region and the drain doped region in the display region and the first patterned metal layer; forming a second patterned metal layer on the interlayer dielectric layer, and filling the second patterned metal layer into the dielectric layer windows, wherein the second patterned metal layer includes metal wires located in the display region and a first sensing electrode located in the photosensitive region; forming a second patterned semiconductor layer on the first sensing electrode, and performing ion doping on the second patterned semiconductor layer to form a first conductive doped region; forming a third patterned semiconductor layer on the first conductive doped region to form an intrinsic region; forming a fourth patterned semiconductor layer on the intrinsic region, and performing ion doping on the fourth patterned semiconductor layer to form a second conductive doped region, wherein the doping ions of the first conductive doped region and those of the second conductive doped region have electric properties opposite to each other; forming an isolating protective layer on the interlayer dielectric layer to cover the second patterned metal layer and the fourth patterned semiconductor layer; forming a plurality of protective layer windows and openings in the isolating protective layer, wherein the protective layer windows are used for exposing the metal wires in the display region, and the openings are used for exposing the second conductive doped region in the photosensitive region; and forming a patterned transparent conductive layer on the isolating protective layer, and filling the patterned transparent conductive layer into the protective layer windows and the openings, wherein the patterned transparent conductive layer includes a pixel electrode electrically connected with the metal wires through the protective layer windows and a second sensing electrode electrically connected with the second conductive doped region through the openings.

Specifically, the above-mentioned ion doping is P-type ion doping or N-type ion doping.

According to an embodiment of the present disclosure, the second patterned semiconductor layer, the third patterned semiconductor layer and the fourth patterned semiconductor layer may all be amorphous silicon layers.

According to an embodiment of the present disclosure, the second patterned semiconductor layer, the third patterned semiconductor layer and the fourth patterned semiconductor layer may all be microcrystalline silicon layers.

According to an embodiment of the present disclosure, the second patterned semiconductor layer and the fourth patterned semiconductor layer may both be microcrystalline silicon layers, and the third patterned semiconductor layer may be an amorphous silicon layer.

Compared with the prior art, the photosensitive unit provided in the present disclosure has the advantage that a PIN structure is adopted for photoelectric conversion, and the generated photocurrent has low probability of dramatic change due to the fluctuation of a working voltage, and thus the accuracy is relatively high. In addition, because the photosensitive unit preferably has the PIN structure arranged longitudinally, when the photosensitive unit is configured on the array substrate of the display panel, the sizes of the length, width and height of the intrinsic region can be designed in a more flexible manner. Therefore, the photosensitive region of the photosensitive unit can be enlarged to a maximum extent, and the photoelectric conversion efficiency can be improved. Consequently, the array substrate of the display panel including the photosensitive unit and the display panel have better ambient light sensing capability, high sensitivity and high reliability. The present disclosure is applicable to various display panels.

### BRIEF DESCRIPTION OF THE DRAWINGS

The accompanying drawings are provided for further understanding of the present disclosure, constitute a part of the description, and are used for interpreting the present disclosure together with the embodiments of the present disclosure, rather than limiting the present disclosure. In the accompanying drawings:

FIG. 1 is a structural section view of an array substrate of a liquid crystal display panel in the prior art;

FIG. 2 is a structural section view of an array substrate of another liquid crystal display panel in the prior art;

FIG. 3 is a structural schematic diagram of a photosensitive unit according to the present disclosure;

FIG. 4 is a structural section view of an array substrate of a display panel of an embodiment according to the present disclosure.

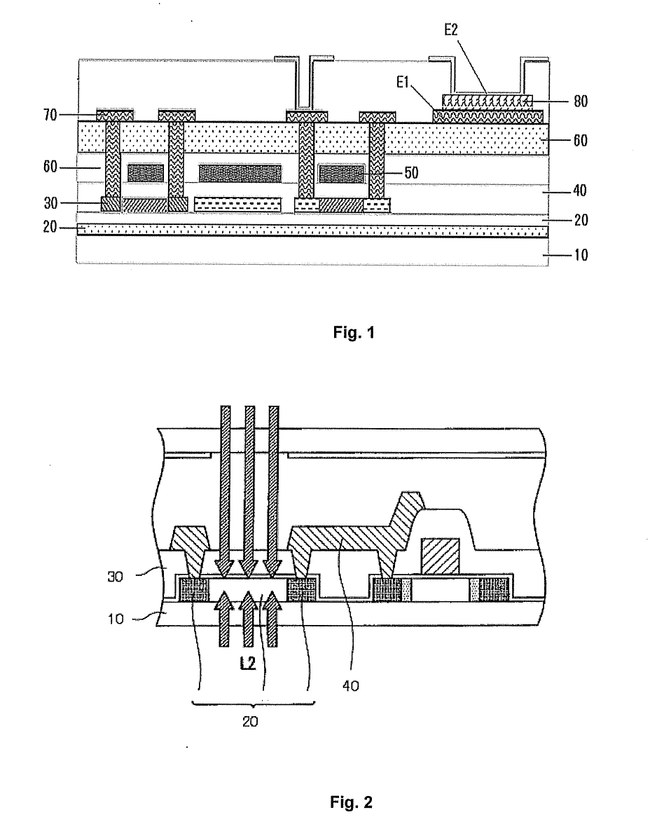

### DETAILED DESCRIPTION OF THE EMBODIMENTS

To enable the objectives, technical solutions and advantages of the present disclosure clearer, the present disclosure will be further illustrated in detail below in conjunction with the specific embodiments and accompanying drawings.

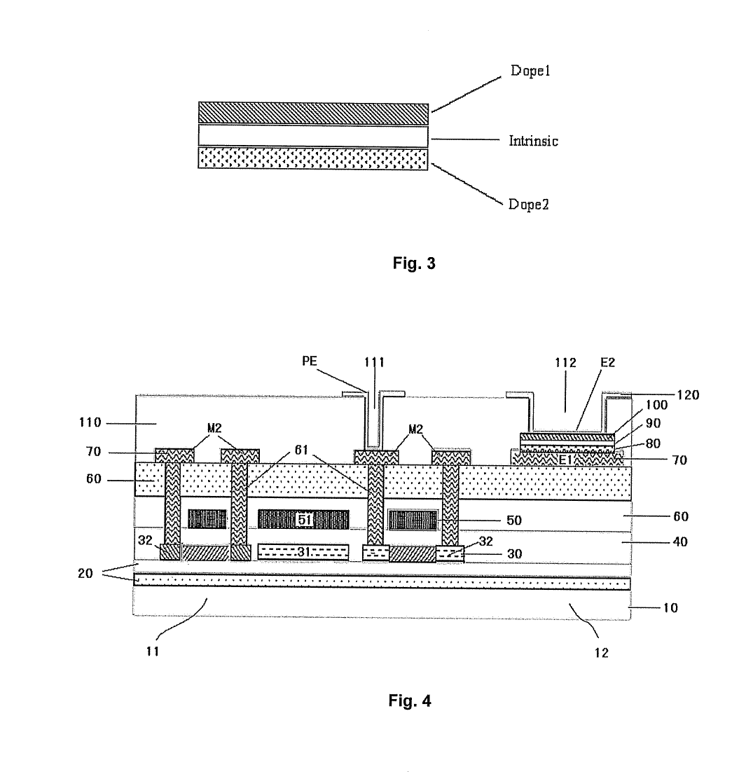

As shown in FIG. 3, a photosensitive unit provided in the present disclosure is configured on an array substrate of a display panel, and includes: a first conductive doped region Dope1; a second conductive doped region Dope2; an intrinsic region Intrinsic arranged between the first conductive doped region Dope1 and the second conductive doped region Dope2; and a first sensing electrode E1 and a second sensing electrode E2 electrically connected with the first conductive doped region Dope1 and the second conductive doped region Dope2 respectively. According to the present disclosure, the doping ions of the first conductive doped region Dope1 and those of the second conductive doped region Dope2 have opposite electrical properties.

In order to select the sizes of the length, width and height of the intrinsic region in a flexible manner so as to enlarge a photosensitive region of the photosensitive unit and improve the photoelectric conversion efficiency, according to the present disclosure, the first conductive doped region Dope1, the second conductive doped region Dope2 and the intrinsic region Intrinsic are preferably arranged along the longitudinal direction.

Specifically, the first conductive doped region Dope1 may be made of P-type or N-type ion doped amorphous silicon, correspondingly, the second conductive doped region Dope2 may be made of N-type or P-type ion doped amorphous silicon, and the intrinsic region Intrinsic may be made of non-doped amorphous silicon.

Moreover, the first conductive doped region Dope1 may be made of P-type or N-type ion doped microcrystalline silicon, correspondingly, the second conductive doped region Dope2 may be made of N-type or P-type ion doped microcrystalline silicon, and the intrinsic region Intrinsic may be made of non-doped microcrystalline silicon.

Further, the first conductive doped region Dope1 may be made of P-type or N-type ion doped microcrystalline silicon, correspondingly, the second conductive doped region Dope2 may be made of N-type or P-type ion doped microcrystalline silicon, and the intrinsic region Intrinsic may be made of non-doped amorphous silicon.

As shown in FIG. 4, according to an embodiment of the present disclosure, an array substrate provided with the above-mentioned photosensitive unit includes a substrate 10, including at least one display region 11 and a photosensitive region 12 thereon.

Preferably, a buffer layer 20 formed by successively depositing a silicon nitride SiNx film and a silicon oxide SiOx film is formed on the substrate 10, in order to isolate the substrate from a semiconductor layer.

A first patterned semiconductor layer 30 is arranged on the buffer layer 20, and includes a first storage electrode 31 and a semiconductor block 32 in the display region 11. The first storage electrode 31 and the semiconductor block 32 are subjected to ion doping respectively, thus forming a source doped region Source and a drain doped region Drain in the semiconductor block 32, and a channel region Channel between the source doped region Source and the drain doped region Drain.

A gate insulating layer 40 is further formed on the buffer layer 20, and configured to cover the first patterned semiconductor layer 30.

A first patterned metal layer 50 is arranged on the gate insulating layer 40, and includes a gate region Gate corresponding to the channel region Channel and a second storage electrode 51 corresponding to the first storage electrode 31.

An interlayer dielectric layer 60 formed by successively depositing a silicon oxide SiOx film and a silicon nitride SiNx film is further provided on the gate insulating layer 40, in order to cover the first patterned metal layer 50.

A plurality of penetrating dielectric layer windows 61 are formed in the interlayer dielectric layer 60 and the gate insulating layer 40, and configured to expose the source doped region Source and the drain doped region Drain in the display region 11, and the first patterned metal layer 50.

A second patterned metal layer 70 is arranged on the interlayer dielectric layer 60, and includes metal wires M2 located in the display region 11 and a first sensing electrode E1 located in the photosensitive region 12. In this case, at the dielectric layer windows 61, the second patterned metal layer 70 is directly deposited on corresponding source doped region Source and drain doped region Drain of the first patterned semiconductor layer 30, and on the first patterned metal layer 50. Therefore, the source doped region Source, the drain doped region Drain and the first patterned metal layer 50 are electrically connected with the metal wires M2 through the dielectric layer windows 61, thus realizing electric connection therebetween or with a peripheral circuit.

A second patterned semiconductor layer 80 is arranged on the first sensing electrode E1, and includes a first conductive doped region Dope1 subjected to ion doping.

A third patterned semiconductor layer 90 is arranged on the first conductive doped region Dope1, and includes an intrinsic region Intrinsic which is not subjected to ion doping.

A fourth patterned semiconductor layer 100 is arranged on the intrinsic region Intrinsic, and includes a second conductive doped region Dope2 subjected to ion doping, wherein the doping ions of the second conductive doped region Dope2 and those of the first conductive doped region Dope1 have opposite electric properties.

An isolating protective layer 110 is further formed on the interlayer dielectric layer 60, and configured to cover the second patterned metal layer 70 and the fourth patterned semiconductor layer 100.

A plurality of penetrating protective layer windows 111 are formed in the isolating protective layer 110 and configured to expose the metal wires M2 in the display region 11. Meanwhile, openings 112 are further formed in the isolating protective layer 110, and configured to expose the second conductive doped region Dope2 in the photosensitive region 12.

A patterned transparent conductive layer 120 is arranged on the isolating protective layer 110, and includes a pixel electrode PE located in the display region 11 and a second sensing electrode E2 located in the photosensitive region 12. In this case, at the protective layer windows 111, the patterned transparent conductive layer 120 is directly deposited on the metal wires M2 of the second patterned metal layer 70, so that the pixel electrode PE is electrically connected with the metal wires M2 through the protective layer windows 111. And at the openings 112, the patterned transparent conductive layer 120 is directly deposited on the second conductive doped region Dope2 of the fourth patterned semiconductor layer 100, so that the second sensing electrode E2 is electrically connected with the second conductive doped region Dope2 through the openings 112.

In the process of manufacturing the above-mentioned array substrate, the first patterned semiconductor layer 30 may be manufactured as follows. A preferably amorphous silicon a-Si material is deposited on the buffer layer and converted into polycrystalline silicon p-Si through laser crystallization. Then, the polycrystalline silicon p-Si is patterned by using yellow light and etching process to form corresponding first storage electrode and semiconductor block. Finally, the first storage electrode and the semiconductor block are subjected to ion doping.

The second and fourth patterned semiconductor layers are subjected to ion doping first during deposition, and then patterned by using yellow light and etching process, wherein the ion doping can be P-type ion doping or N-type ion doping.

The other layers are all manufactured by using yellow light and etching, which is known in the art and will not be explained here.

The foregoing merely relate to preferred specific embodiments of the present disclosure. However, the protection scope of the present disclosure is not limited thereto. Readily conceivable variations or substitutions to one skilled in the art based on the disclosed technical scope of the present disclosure also fall within the protection scope of the present disclosure. Accordingly, the protection scope of the present disclosure should be interpreted on basis of the protection scope of the claims only.

1. A photosensitive unit configured on an array substrate of a display panel, including:
a first conductive doped region;
a second conductive doped region;
an intrinsic region arranged between the first conductive doped region and the second conductive doped region, wherein the doping ions of the first conductive doped region and those of the second conductive doped region have electric properties opposite to each other; and
a first sensing electrode and a second sensing electrode electrically connected with the first conductive doped region and the second conductive doped region respectively.

2. The photosensitive unit according to claim 1, wherein the first conductive doped region, the second conductive doped region and the intrinsic region are arranged longitudinally.

3. The photosensitive unit according to claim 1, wherein the first conductive doped region and the second conductive doped region are made of P-type or N-type ion doped amorphous silicon, and the intrinsic region is an amorphous silicon layer.

4. The photosensitive unit according to claim 2, wherein the first conductive doped region and the second conductive doped region are made of P-type or N-type ion doped amorphous silicon, and the intrinsic region is an amorphous silicon layer.

5. The photosensitive unit according to claim 1, wherein the first conductive doped region and the second conductive doped region are made of P-type or N-type ion doped microcrystalline silicon, and the intrinsic region is a microcrystalline silicon layer.

6. The photosensitive unit according to claim 2, wherein the first conductive doped region and the second conductive doped region are made of P-type or N-type ion doped microcrystalline silicon, and the intrinsic region is a microcrystalline silicon layer.

7. The photosensitive unit according to claim 1, wherein the first conductive doped region and the second conductive doped region are made of P-type or N-type ion doped microcrystalline silicon, and the intrinsic region is an amorphous silicon layer.

8. The photosensitive unit according to claim 2, wherein the first conductive doped region and the second conductive doped region are made of P-type or N-type ion doped microcrystalline silicon, and the intrinsic region is an amorphous silicon layer.

9. An array substrate of a display panel having a photosensitive unit arranged thereon, said photosensitive unit including:
a first conductive doped region;
a second conductive doped region;
an intrinsic region arranged between the first conductive doped region and the second conductive doped region, wherein the doping ions of the first conductive doped region and those of the second conductive doped region have electric properties opposite to each other; and
a first sensing electrode and a second sensing electrode electrically connected with the first conductive doped region and the second conductive doped region respectively.

10. The array substrate of a display panel according to claim 9, wherein the first conductive doped region, the second conductive doped region and the intrinsic region are arranged longitudinally.

11. A method for manufacturing a array substrate of a display panel, including the following steps:
providing a substrate including at least one display region and a photosensitive region;
forming on the substrate a first patterned semiconductor layer including a first storage electrode and a semiconductor block in the display region, and performing ion doping on the first storage electrode and the semiconductor block, so as to form a source doped region and a drain doped region in the semiconductor block and form a channel region between the source doped region and the drain doped region;
forming a gate insulating layer on the substrate to cover the first patterned semiconductor layer;
forming on the gate insulating layer a first patterned metal layer including a gate region corresponding to the channel region and a second storage electrode corresponding to the first storage electrode;
forming an interlayer dielectric layer on the gate insulating layer to cover the first patterned metal layer;
forming a plurality of dielectric layer windows in the interlayer dielectric layer and the gate insulating layer, in order to expose the source doped region and the drain doped region in the display region, and the first patterned metal layer;
forming a second patterned metal layer on the interlayer dielectric layer, and filling the second patterned metal layer into the dielectric layer windows, wherein the second patterned metal layer includes metal wires located in the display region and a first sensing electrode located in a photosensitive region;
forming a second patterned semiconductor layer on the first sensing electrode, and performing ion doping on the second patterned semiconductor layer to form a first conductive doped region;
forming a third patterned semiconductor layer on the first conductive doped region to form an intrinsic region;
forming a fourth patterned semiconductor layer on the intrinsic region, and performing ion doping on the fourth patterned semiconductor layer to form a second conductive doped region, wherein the doping ions of the first conductive doped region and those of the second conductive doped region have electric properties opposite to each other;
forming an isolating protective layer on the interlayer dielectric layer to cover the second patterned metal layer and the fourth patterned semiconductor layer;
forming a plurality of protective layer windows and openings in the isolating protective layer, wherein the protective layer windows are used for exposing the metal wires in the display region, and the openings are used for exposing the second conductive doped region in the photosensitive region; and
forming a patterned transparent conductive layer on the isolating protective layer, and filling the patterned transparent conductive layer into the protective layer windows and the openings, wherein the patterned transparent conductive layer includes a pixel electrode electrically connected with the metal wires through the protective layer windows and a second sensing electrode electrically connected with the second conductive doped region through the openings.

12. The method according to claim 11, wherein the ion doping is P-type ion doping or N-type ion doping.

13. The method according to claim 11, wherein the second patterned semiconductor layer, the third patterned semiconductor layer and the fourth patterned semiconductor layer are all amorphous silicon layers.

14. The method according to claim 12, wherein the second patterned semiconductor layer, the third patterned semiconductor layer and the fourth patterned semiconductor layer are all amorphous silicon layers.

15. The method according to claim 11, wherein the second patterned semiconductor layer, the third patterned semiconductor layer and the fourth patterned semiconductor layer are all microcrystalline silicon layers.

16. The method according to claim 12, wherein the second patterned semiconductor layer, the third patterned semiconductor layer and the fourth patterned semiconductor layer are all microcrystalline silicon layers.

17. The method according to claim 11, wherein the second patterned semiconductor layer and the fourth patterned semiconductor layer are both microcrystalline silicon layers, and the third patterned semiconductor layer is an amorphous silicon layer.

18. The method according to claim 12, wherein the second patterned semiconductor layer and the fourth patterned semiconductor layer are both microcrystalline silicon layers, and the third patterned semiconductor layer is an amorphous silicon layer.
